(19) United States
(12) Patent Application Publication
(10) Pub. No.: US 2002/0072209 A1
(43) Pub. Date: Jun. 13, 2002

(54) Method of forming tungsten nitride layer as metal diffusion barrier in gate structure of MOSFET device

(75) Inventor: Horng-Huei Tseng, Hsinchu (TW)

Correspondence Address: Daniel R. McClure, THOMAS, KAYDEN, HORSTEMEYER & RISLEY, L.L.P., Suite 1750, 100 Galleria Parkway, N.W., Atlanta, GA, 30339-5948, US

(73) Assignee: Vanguard International Semiconductor Corporation, Hsinchu (TW)

(21) Appl. No.: 09/734,837

(22) Filed: Dec. 11, 2000

(51) Int. Cl. H01L 21/3205

(52) U.S. Cl. 438/592

(57) ABSTRACT

A method of forming a polysilicon gate structure of a MOSFET device includes a tungsten nitride layer formed between the polysilicon gate layer and the tungsten silicide layer covered on the polysilicon gate layer. The formation of tungsten nitride layer comprises depositing a tungsten layer on the polysilicon layer and implanting nitrogen ions into the tungsten layer to form a nitrogen-implanted tungsten layer. Thermal treatment is applied to convert the nitrogen-implanted tungsten layer into a tungsten nitride layer that will serve as a metal diffusion barrier in subsequent process to inhibit penetration of metal into the polysilicon gate layer, thereby increasing stability and reliability of the device.

### FIELD OF THE INVENTION

The present invention relates generally to the manufacture of a gate structure of a MOS device in an integrated circuit (IC) on a semiconductor substrate, and more particularly, to a method of forming a polysilicon gate electrode of a MOSFET device wherein a tungsten nitride layer is formed between the polysilicon gate layer and the tungsten silicide layer thereof to serve as a diffusion barrier to inhibit penetration of metal into the polysilicon gate layer.

### BACKGROUND OF THE INVENTION

As more strict design rule for elements of integrated circuit structure in semiconductor devices such as dynamic random access memories (DRAMs) is required in the development of marking the microelectronic elements smaller and closer, a greater restraint has been imposed on using materials of high resistivity, such as polysilicon, as the gate electrode of the elements, and therefore many studies for lowering the resistivity of the gate electrode have been carried out in order to overcome the restraint. Polycides are used in the gate structure of MOSFET devices due to their low resistivies as well as stabilities. A typical polycide gate electrode of a MOSFET device includes a stack structure, such as cap insulator/tungsten silicide/polysilicon, formed on a gate oxide layer. However, the subsequent heat process may result in metal penetration into the polysilicon gate layer, thereby degrading device reliability.

In U.S. Pat. No. 5,837,598, Aronowitz et al. teach the formation of a diffusion barrier at the polysilicon/gate dielectric interface for the underlying gate oxide and semiconductor substrate to be not penetrated by the dopant of the polysilicon gate electrode, wherein a very thin layer of amorphous or polycrystalline silicon is exposed to a nitrogen plasma, resulting in the formation of a barrier layer containing silicon and nitrogen at the surface of the thin silicon layer, and then polysilicon is deposited over the barrier layer. The diffusion barrier is to prevent the gate oxide and substrate from diffusion of dopant in the polysilicon gate layer.

U.S. Pat. No. 6,096,614 issued to Wu describes a method of fabricating a MOS device without boron penetration wherein a thin stacked-amorphous-silicon layer is deposited over a gate oxide layer, lightly implanted with nitrogen ions, patterned to define a gate structure, and thermally annealed to segregated the nitrogen ions in the stacked-amorphous-silicon layer into the gate oxide layer to act as a diffusion barrier, and the stacked-amorphous-silicon gate is converted into polysilicon gate. The main objective is to form a barrier for prevention of boron penetration through the gate oxide into silicon substrate.

In the process of U.S. Pat. No. 5,300,455 issued to Vuillermoz et al., a top tungsten layer is deposited on a silicon layer of source/drain and gate zones, the tungsten/silicon interface is subjected to a nitrogen-based plasma during a period of at least five minutes and brought to a temperature greater than 500° C. in order to create a diffusion barrier, and then the interface is subjected to an annealing treatment under a neutral atmosphere so as to remove the nitrogen previously introduced into the tungsten layer. The Vuillermoz patent is to prevent the tungsten from reacting with the underlying silicon to form tungsten silicide in subsequent process for double metal interconnection.

U.S. Pat. No. 5,604,140 issued to Byun proposes a method of forming a fine titanium nitride film as a barrier layer covered on an oxygen-stuffed titanium nitride film in a MOS transistor gate structure, wherein a titanium nitride film is deposited on a polysilicon gate layer and then exposed to atmosphere to introduce oxygen into the titanium nitride film, and the barrier titanium nitride film is deposited on the titanium nitride film having oxygen stuffed therein and then converted into a fine titanium nitride film by two times of a heat treatment process. The fine titanium nitride film is suitable for a DRAM device to prevent high temperature diffusion of the bit line metal thereof. In contrast, the present invention uses tungsten nitride as a barrier in conjunction with tungsten silicide in a polysilicon gate structure to inhibit metal diffusion, which is a different approach and objective.

In U.S. Pat. Nos. 5,923,999 and 6,114,736, Balasubramanyam et al. introduce a tungsten nitride layer into the gate structure of a MOSFET device between the tungsten silicide layer and the polysilicon layer to serve as a barrier to prevent migration of dopant form the polysilicon layer into the tungsten silicide layer in the post gate heat cycles and migration of metallic impurities from the tungsten silicide layer into the underlying polysilicon gate layer and gate oxide layer. The main purpose of the tungsten nitride is to provide higher thermal stability than titanium nitride, and in the process disclosed, tungsten nitride (W_{y}N) is formed over the doped polysilicon gate layer by reactive sputtering, chemical vapor deposition (CVD), or sputtered tungsten plus NH₃ anneal. In addition, a standard step of heating to 150° C. and degassing in a vacuum chamber is applied prior to the tungsten nitride (W_{y}N) deposition, and the tungsten rich tungsten nitride (W_{y}N) is annealed to become W₂N phase after the gate is completely formed. However, the present invention is to provide an alternative process of forming tungsten nitride layer as a metal diffusion barrier in the gate structure of a MOSFET device, which is a different procedure and approach.

### SUMMARY OF THE INVENTION

An object of the present invention is to disclose a method of forming a polysilicon gate electrode of a MOSFET device wherein a tungsten nitride layer is formed between the polysilicon gate layer and the tungsten silicide layer thereof to serve as a diffusion barrier to inhibit penetration of metal into the polysilicon gate layer, thereby increasing stability and reliability of the device.

According to the present invention, a method of forming a polysilicon gate electrode of a MOSFET device comprises depositing a polysilicon layer over a gate oxide layer on a semiconductor substrate. A tungsten layer is deposited on the polysilicon layer and then implanted with nitrogen ions to form a nitrogen-implanted tungsten layer. The nitrogen-implanted tungsten layer is thermally treated to be converted into a tungsten nitride layer that will serve as a metal diffusion barrier in subsequent process. Tungsten silicide is deposited on the barrier tungsten nitride layer, and a cap dielectric is covered on the tungsten silicide. The cap dielectric, tungsten silicide, tungsten nitride, polysilicon, and gate oxide are patterned to form a gate structure.

### BRIEF DESCRIPTION OF THE DRAWINGS

These and other objects, features and advantages of the present invention will become apparent to those skilled in the art upon consideration of the following description of the preferred embodiments of the present invention taken in conjunction with the accompanying drawings, in which:

FIGS. 1 to FIG. 5 illustrate the drawings of the first embodiment of the present invention;

FIGS. 6 to FIG. 9 illustrate the drawings of the second embodiment of the present invention;

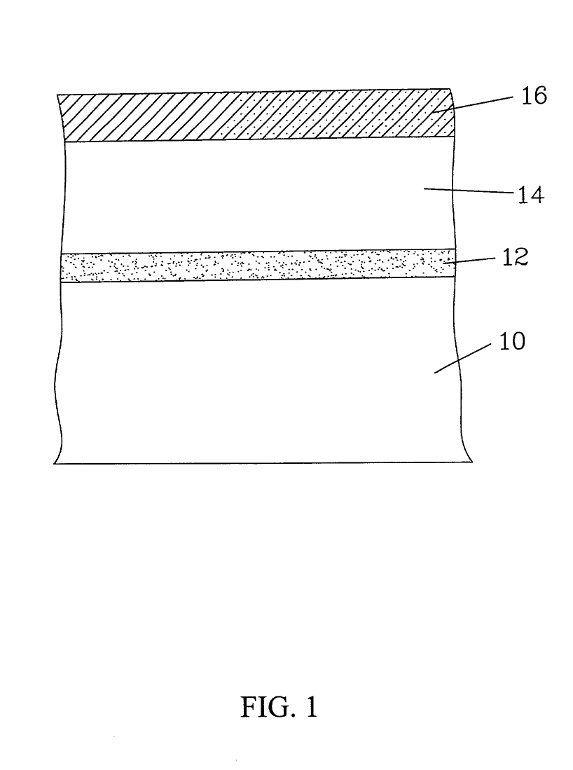

FIG. 1 is a cross-sectional view of a semiconductor substrate 10 with a gate oxide layer 12, a polysilicon layer 14, and a tungsten layer 16 formed in stack thereon;

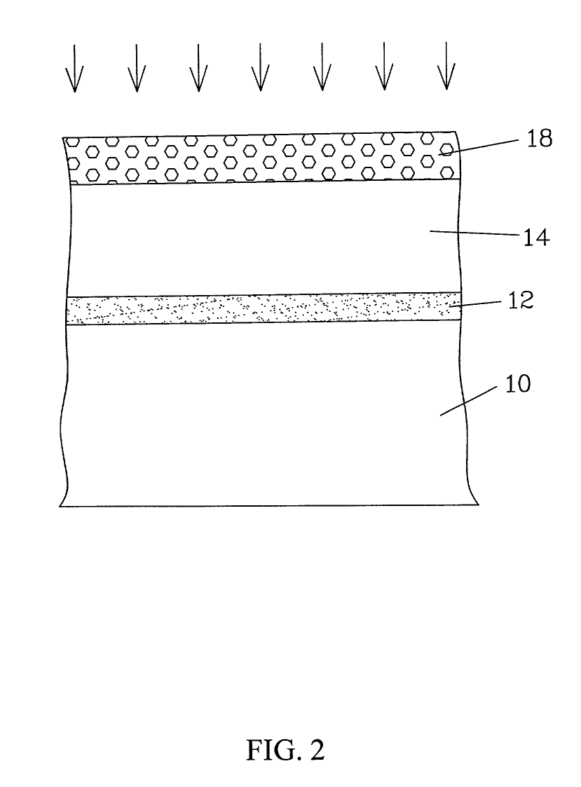

FIG. 2 is a cross-sectional view of the tungsten layer 16 in FIG. 1 implanted with nitrogen to form a nitrogen-implanted tungsten layer 18;

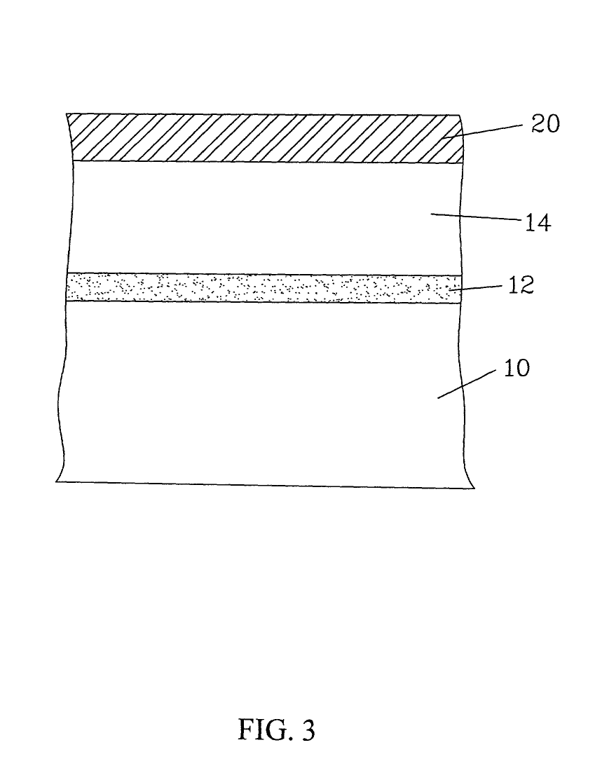

FIG. 3 is a cross-sectional view of the nitrogen-implanted tungsten layer 18 in FIG. 2 thermally treated to be converted into a tungsten nitride layer 20;

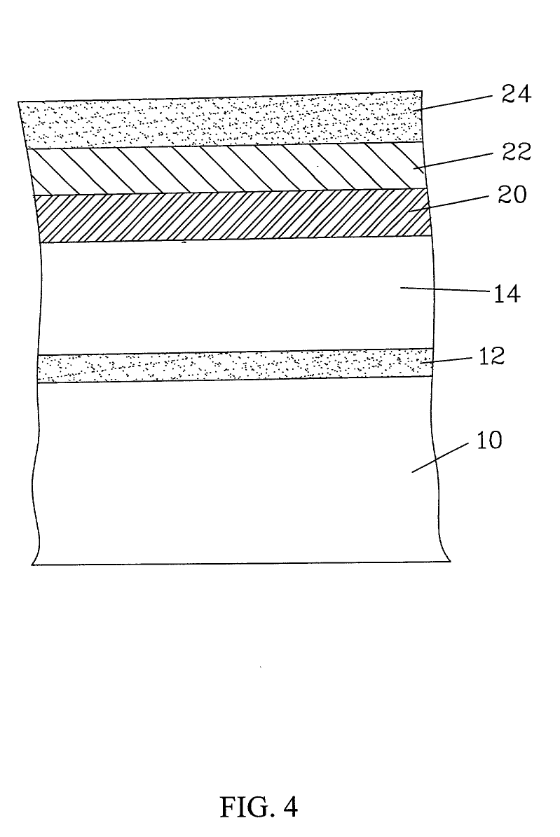

FIG. 4 is a cross-sectional view of the structure after a tungsten suicide layer 22 and a cap dielectric layer 24 are sequentially deposited on the structure in FIG. 3;

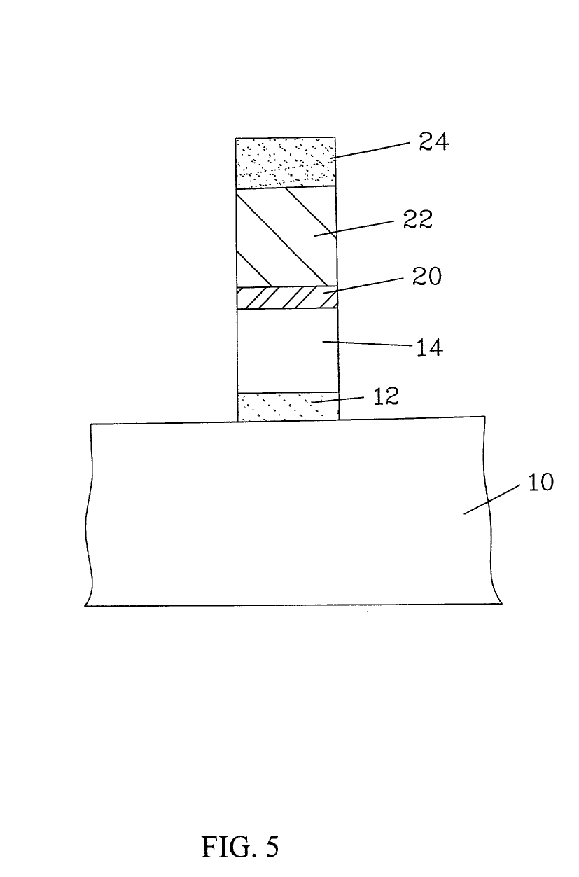

FIG. 5 is a cross-sectional view after the structure in FIG. 4 is patterned to form a gate structure;

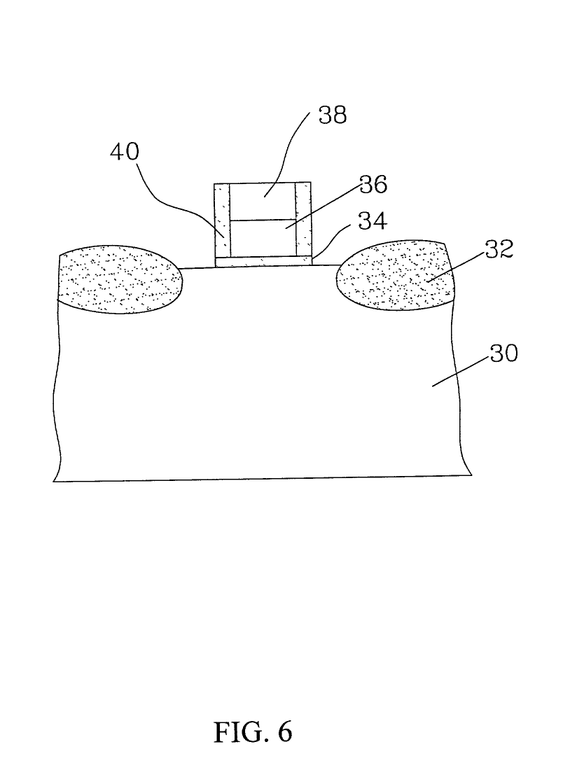

FIG. 6 is a cross-sectional view after a gate oxide layer 34, a polysilicon layer 36, a sacrificial layer 38, and a spacer 40 are formed on a substrate 30 with isolation 32;

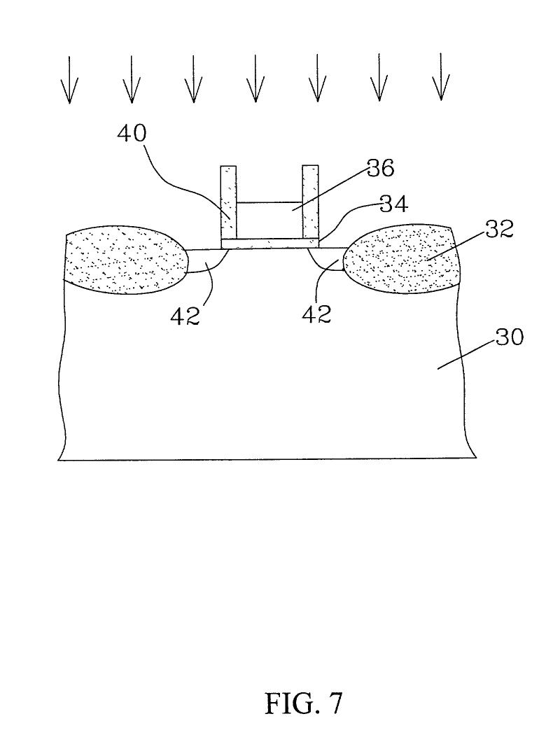

FIG. 7 is a cross-sectional view of the structure after the sacrificial layer 38 is removed and source/drain regions 42 are formed in the structure shown in FIG. 6;

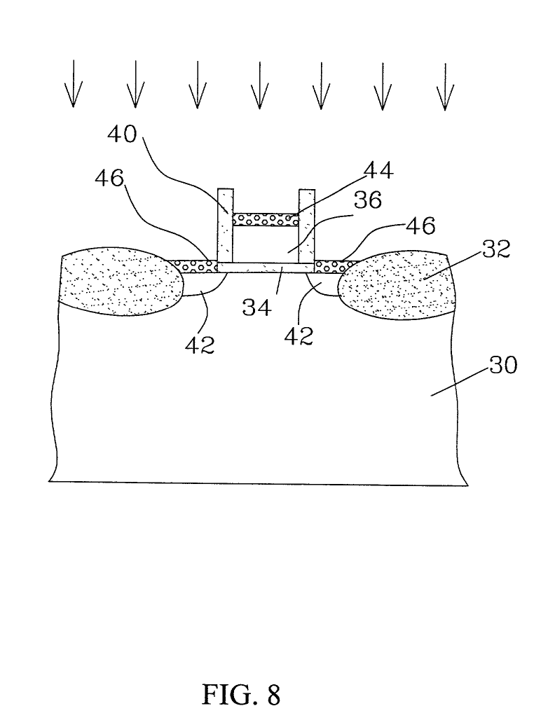

FIG. 8 is a cross-sectional view when a tungsten layer is formed and then implanted with nitrogen to form a nitrogen-implanted tungsten layer 44 and 46 following with FIG. 7; and

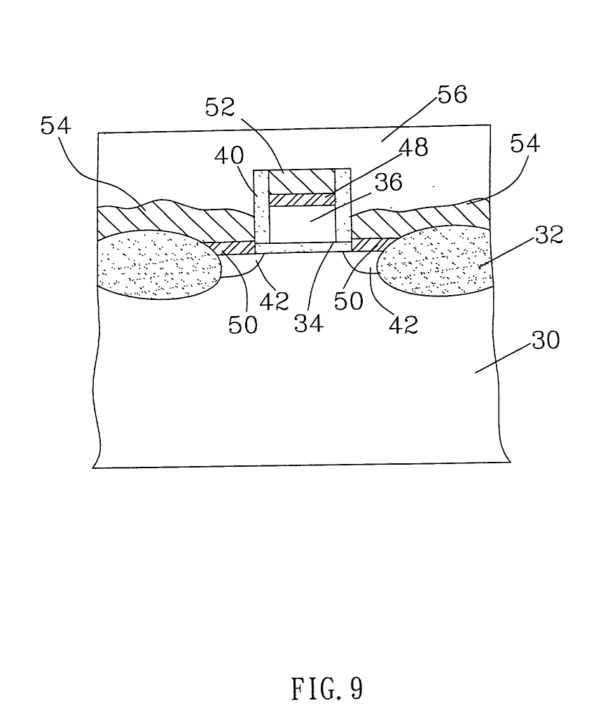

FIG. 9 is a cross-sectional view after the nitrogen-implanted tungsten layer 44 and 46 in FIG. 8 is thermally treated to be converted into a tungsten nitride layer 48 and 50, and a tungsten silicide layer 52 and 54 and a cap dielectric layer 56 are deposited on the resultant structure.

### DETAILED DESCRIPTION OF THE INVENTION

A starting structure for the first embodiment of the present invention is shown in FIG. 1, in which a gate oxide layer 12 in a thickness of about 50-300 Å is grown upon a semiconductor substrate 10 and a polysilicon layer 14 in a thickness of about 500-3000 Å is deposited on the gate oxide layer 12. Then, a tungsten layer 16 is deposited on the polysilicon layer 14.

As shown in FIG. 2, implantation of nitrogen ions is performed for the tungsten layer 16 to become a nitrogen-implanted tungsten layer 18. The nitrogen implantation is done by a conventional implantor at a density of 10¹⁴ −10¹⁶ cm^{31 2} with an energy of 20-100 keV. Thermal treatment is subsequently applied to convert the nitrogen-implanted tungsten layer 18 into a tungsten nitride layer 20, as shown in FIG. 3. This process can be performed by placing the substrate 10 with the nitrogen-implanted tungsten layer 18 in a vacuum chamber or in an atmosphere of nitrogen/argon gas and increasing the temperature above 800° C. in a period of at least 3 minutes. The tungsten nitride layer 20 thus formed will serve as a metal diffusion barrier to inhibit metal penetration into the underlying polysilicon layer 14.

Referring to FIG. 4, now a tungsten silicide layer 22 is deposited with a thickness from about 500 Å to about 1000 Å on the tungsten nitride layer 20 by a CVD or sputtering process. A cap dielectric layer 24 such as silicon dioxide and silicon nitride is deposited with a thickness of 500-1500 Å to cover the tungsten silicide layer 22 preferably by a CVD process. If silicon nitride is selected for the cap dielectric layer 24, it can be formed by low pressure CVD (LPCVD). The cap dielectric layer 24, tungsten silicide layer 22, tungsten nitride layer 20, polysilicon layer 14, and gate oxide layer 12 are patterned by an isotropic vertical etching process to form a gate structure for a MOSFET device, as shown in FIG. 5.

For the second embodiment of the present invention, a starting structure is shown in FIG. 6. A semiconductor substrate 30 with isolation 32 formed thereon is provided. A gate oxide layer 34 is formed and patterned on the substrate 30. A polysilicon layer 36 and a sacrificial layer 38 with an insulation spacer 40 are formed upon the gate oxide layer 34. As shown in FIG. 7, the sacrificial layer 38 is removed and ion implantation is then applied to form source/drain regions 42 on the substrate 30 and dope the polysilicon layer 36 surrounded by the insulation spacer 40.

In accordance with the process which forms the subject of the present invention, and as shown in FIG. 8, a tungsten layer is deposited on the polysilicon layer 36 and source/drain regions 42 and then implanted with nitrogen ions to form nitrogen-implanted tungsten layer 44 and 46. Subsequently, the nitrogen-implanted tungsten layer 44 and 46 is applied with thermal treatment to convert it into tungsten nitride 48 and 50, as shown in FIG. 9. The tungsten nitride layer 48 and 50 thus serve as a metal diffusion barrier to inhibit metal penetration into the underlying polysilicon layer 36 and source/drain regions 42. After that, tungsten silicide 52 and 54 is deposited on the tungsten nitride 48 and 50, and a thick cap dielectric layer 56 is formed on the resultant structure for example by decomposition of Tetra-Ethyl-Ortho-Silicate (TEOS).

While the present invention has been described in conjunction with preferred embodiments thereof, it is evident that many alternatives, modifications and variations will be apparent to those skilled in the art. Accordingly, it is intended to embrace all such alternatives, modifications and variations that fall within the spirit and scope thereof as set forth in the appended claims.

What is claimed is:

1. A method of forming a gate structure of a MOSFET device comprising the steps of:
forming a gate oxide layer on a substrate;
depositing a polysilicon layer on said gate oxide layer;
depositing a tungsten layer on said polysilicon layer;
implanting nitrogen into said tungsten layer for forming a nitrogen-implanted layer;
converting said nitrogen-implanted layer into a tungsten nitride layer;
depositing a tungsten silicide layer on said tungsten nitride layer;
depositing a cap dielectric layer on said tungsten silicide layer; and
patterning said cap dielectric layer, tungsten silicide layer, tungsten nitride layer, polysilicon layer, and gate oxide layer.

2. A method according to claim 1, wherein said nitrogen-implanted layer is thermally treated to be converted into said tungsten nitride layer.

3. A method of forming a MOSFET structure on a semiconductor substrate, said method comprising the steps of:
forming a gate oxide layer on a substrate;
depositing a polysilicon layer on said gate oxide layer;
depositing a tungsten layer on said polysilicon layer;
implanting nitrogen into said tungsten layer for forming a nitrogen-implanted layer;
converting said nitrogen-implanted layer into a tungsten nitride layer;
depositing a tungsten silicide layer on said tungsten nitride layer;
depositing a cap dielectric layer on said tungsten silicide layer; and

4. A method according to claim 3, wherein said nitrogen-implanted layer is thermally treated to be converted into said tungsten nitride layer.
